(19) United States
(12) Patent Application Publication
(10) Pub. No.: US 2021/0408127 A1
(43) Pub. Date: Dec. 30, 2021

(54) COLOR FILTER SUBSTRATE, DISPLAY PANEL, AND MANUFACTURING METHOD THEREOF

(71) Applicant: SHENZHEN CHINA STAR OPTOELECTRONICS SEMICONDUCTOR DISPLAY TECHNOLOGY CO., LTD., Shenzhen (CN)

(72) Inventor: Liangfen ZHANG, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 16/617,518

(22) PCT Filed: Nov. 5, 2019
(86) PCT No.: PCT/CN2019/115710

§ 371 Date: Nov. 27, 2019

(30) Foreign Application Priority Data
Sep. 16, 2019 (CN) 201910869218.3

(51) Int. Cl. H01L 27/32; H01L 51/52; H01L 51/56

(52) U.S. Cl. CPC H01L 27/322; H01L 51/5228; H01L 51/56; H01L 27/3262; H01L 51/5212; H01L 27/3272; H01L 51/5284

(57) ABSTRACT

A color filter substrate, a display panel, and a manufacturing method thereof. The color filter substrate comprises an auxiliary cathode layer, a photoresist layer, an RGB color resist layer, a black matrix, and a glass substrate, which are disposed in sequence. Wherein, a thickness of the photoresist layer which is directly below the black matrix area is greater than a thickness of the photoresist layer which is not directly below the black matrix area, and the auxiliary cathode layer is disposed under the photoresist layer which is under the black matrix area.

### FIELD OF INVENTION

The present disclosure relates to the field of display technologies, and more particularly to a display panel and a manufacturing method thereof.

### BACKGROUND OF INVENTION

Organic light-emitting diodes (OLEDs) have display characteristics and quality that are superior to LCDs, and advantages of OLED include light and thin properties, short response times, low driving voltages, better viewing angles, and better color display. OLEDs receive widespread attention, and has been rapidly developing in recent years. Developments include not only manufacturing of curved displays, but also large sizes. However, a large size OLED has problems of voltage drops, especially for top emitting panels, visually visible mura (non-uniform brightness), and voltage drop caused by a thinner cathode, which need to be solved.

In current techniques, the occurrence of voltage drop is reduced by manufacturing auxiliary electrodes and cathode spacers, and achieving individual control of a cathode by changing the cathode from an original full-face film to an isolation electrode and connecting the cathode to the lower auxiliary electrodes; or using laser to burn out the organic light-emitting layer, thereby achieving the effect of connecting the cathode and the auxiliary electrodes.

Therefore, it is necessary to develop a manufacturing method of a new type of display panel to overcome the shortcomings of the current techniques.

An objective of the present disclosure is to provide a color filter substrate which can solve the voltage drop problem caused by a thinner cathode of a display panel in current techniques.

### SUMMARY OF INVENTION

To achieve the above object, an embodiment of the present disclosure provides a color filter substrate. The color filter substrate comprises an auxiliary cathode layer, a photoresist layer, an RGB color resist layer, a black matrix, and a glass substrate disposed in sequence, wherein a thickness of the photoresist layer which is directly below a black matrix area is greater than a thickness of the photoresist layer which is not directly below the black matrix area; the auxiliary cathode layer is disposed under the photoresist layer which is under the black matrix area.

An embodiment of the present disclosure provides a display panel. The display panel comprises a thin film transistor substrate, an anode layer, a flat layer, an organic light emitting layer, a cathode layer, and the above color filter substrate disposed in sequence; wherein the auxiliary cathode layer is connected to the cathode layer.

In an embodiment of the present disclosure, a material of the flat layer is a polyimide film.

In an embodiment of the present disclosure, a material for the anode layer comprises one of indium tin metal oxide or silver metal.

In an embodiment of the present disclosure, the thin film transistor substrate comprises a substrate layer, a light-shielding layer, a buffer layer, an active layer, a gate insulating layer, a gate layer, an interlayer dielectric layer, a source/drain layer, and an organic layer disposed in sequence.

In an embodiment of the present disclosure, a material of the source/drain layer comprises one of the following: molybdenum, aluminum, titanium, copper, or indium tin metal oxide.

In an embodiment of the present disclosure, a material of the gate insulating layer comprises one of silicon oxide or silicon nitride.

To achieve the above object, an embodiment of the present disclosure further provides a manufacturing method of the display panel. The method comprises the following steps:

step S1: providing the thin film transistor substrate, and manufacturing the anode layer on the thin film transistor substrate;

step S2: manufacturing the flat layer on the anode layer;

step S3: manufacturing the organic light emitting layer on the flat layer;

step S4: manufacturing the cathode layer on the organic light emitting layer, and forming the thin film transistor backboard;

step S5: providing the glass substrate, and manufacturing the black matrix on the glass substrate;

step S6: manufacturing the RGB color resist layer on the black matrix;

step S7: manufacturing the photoresist layer on the RGB color resist layer, wherein the thickness of the photoresist layer which is on the black matrix area is greater than the thickness of the photoresist layer which is not on the black matrix area;

step S8: manufacturing the auxiliary cathode layer on the photoresist layer which is on the black matrix area, and forming the color filter substrate; and

step S9: bonding the thin film transistor backboard to the color filter substrate.

In an embodiment of the present disclosure, the flat layer is manufactured by chemical vapor deposition.

In an embodiment of the present disclosure, the photoresist layer is manufactured by a semi-transparent mask technique or a method of two masks.

In an embodiment of the present disclosure, the step S9 of bonding the thin film transistor backboard to the color filter substrate is by a packaging method.

Compared to current techniques, the beneficial effect of the present disclosure is: the present disclosure provides a color filter substrate, a display panel, and a manufacturing method thereof. When manufacturing a color filter substrate, use a semi-transparent mask technique or a method of two masks to manufacture a photoresist layer which is thicker directly on the black matrix, and then manufacture an auxiliary cathode layer on the photoresist layer which is on the black matrix area. The auxiliary cathode layer is higher because the below photoresist layer is higher, facilitating the auxiliary cathode layer to connect to the cathode layer when the color filter substrate is bonded to the thin film transistor backboard. Because the impedance of the auxiliary cathode layer is less, after contacting with the cathode layer, the resistance of the cathode layer will decrease at the same time, thereby reducing the voltage drop, improving the problem of voltage drops in display panels, and improving quality of display panels.

### DESCRIPTION OF DRAWINGS

The accompanying figures to be used in the description of embodiments of the present disclosure or prior art will be described in brief to more clearly illustrate the technical solutions of the embodiments or the prior art. The accompanying figures described below are only part of the embodiments of the present disclosure, from which those skilled in the art can derive further figures without making any inventive efforts.

FIG. 1 is a schematic structural diagram of a display panel according to embodiment 1 of the present disclosure.

FIG. 2 is a flowchart of a manufacturing method of a display panel according to embodiment 1 of the present disclosure.

FIG. 3 is a schematic structural diagram of a display panel when manufactured in step S1 according to embodiment 1 of the present disclosure.

FIG. 4 is a schematic structural diagram of a display panel when manufactured in step S2 according to embodiment 1 of the present disclosure.

FIG. 5 is a schematic structural diagram of a display panel when manufactured in step S3 according to embodiment 1 of the present disclosure.

FIG. 6 is a schematic structural diagram of a display panel when manufactured in step S4 according to embodiment 1 of the present disclosure.

FIG. 7 is a schematic structural diagram of a display panel when manufactured in step S5 according to embodiment 1 of the present disclosure.

FIG. 8 is a schematic structural diagram of a display panel when manufactured in step S6 according to embodiment 1 of the present disclosure.

FIG. 9 is a schematic structural diagram of a display panel when manufactured in step S7 according to embodiment 1 of the present disclosure.

FIG. 10 is a schematic structural diagram of a display panel when manufactured in step S8 according to embodiment 1 of the present disclosure.

FIG. 11 is a schematic structural diagram of a display panel when manufactured in step S9 according to embodiment 1 of the present disclosure.

### DETAILED DESCRIPTION OF PREFERRED EMBODIMENTS

The embodiments of the present disclosure are described in detail hereinafter. Examples of the described embodiments are given in the accompanying drawings. The specific embodiments described with reference to the attached drawings are all exemplary and are intended to illustrate and interpret the present disclosure, which shall not be construed as causing limitations to the present disclosure.

The specific structural and detailed functions disclosed are merely representative and are for the purpose of describing exemplary embodiments of the disclosure. The preferred embodiment is not intended to limit the present disclosure, and it is understood that many changes and modifications to the described embodiment can be carried out without departing from the scope and the spirit of the disclosure.

### Embodiment 1

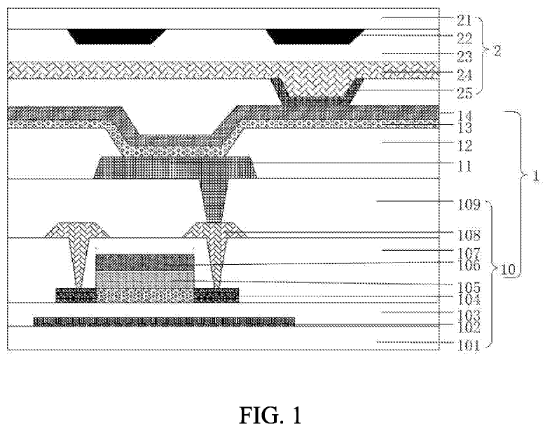

The embodiment of the present disclosure provides a display panel. Referring to FIG. 1, FIG. 1 is a schematic structural diagram of a display panel according to embodiment 1 of the present disclosure. The display panel comprises a thin film transistor backboard 1 and a color filter substrate 2 disposed on the thin film transistor backboard 1.

The thin film transistor backboard 1 comprises a thin film transistor substrate 10, an anode layer 11 disposed on the thin film transistor substrate 10, a flat layer 12 disposed on the anode layer 11, an organic light emitting layer 13 disposed on the flat layer 12, and a cathode layer 14 disposed on the organic light-emitting layer 13.

A material of the flat layer 12 is a polyimide film. A material of the anode layer 11 can be indium tin metal oxide or silver metal, which is not limited here.

The thin film transistor substrate 10 comprises a substrate layer 101, a light-shielding layer 102, a buffer layer 103, an active layer 104, a gate insulating layer 105, a gate layer 106, an interlayer dielectric layer 107, a source/drain layer 108, and an organic layer 109, which are disposed in sequence.

A material of the source/drain layer 108 comprises one of the following: molybdenum, aluminum, titanium, copper, or indium tin metal oxide. A material of the gate insulating layer 105 comprises one of silicon oxide or silicon nitride.

The color filter substrate 2 comprises an auxiliary cathode layer 25, a photoresist layer 24, an RGB color resist layer 23, a black matrix 22, and a glass substrate 21, which are disposed in sequence.

Wherein a thickness of the photoresist layer 24 which is directly below the black matrix 22 area is greater than a thickness of the photoresist layer which is not directly below the black matrix area. The auxiliary cathode layer 25 is disposed under the photoresist layer 24 which is under the black matrix 22 area. The auxiliary cathode layer 25 is connected to the cathode layer 14.

Because the impedance of the auxiliary cathode layer is less, after contacting with the cathode layer, the resistance of the cathode layer will decrease at the same time, thereby reducing the voltage drop, improving the problem of voltage drops in display panels, and improving quality of display panels.

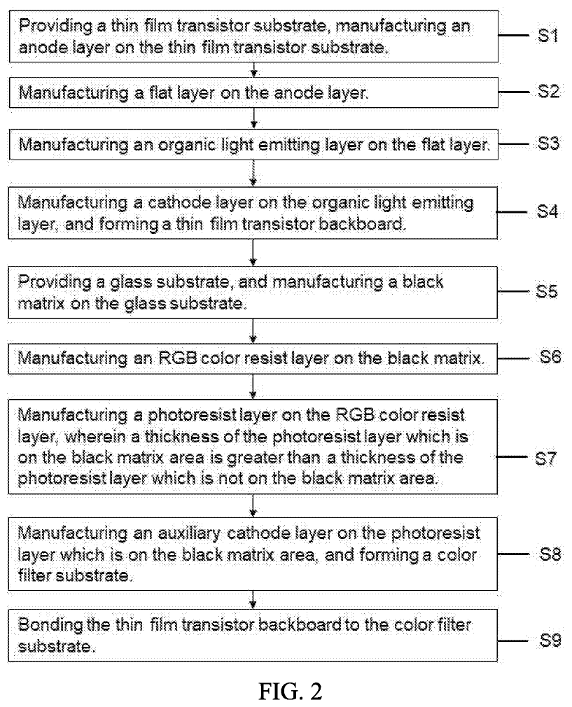

The embodiment of the present disclosure further provides a manufacturing method of the display panel. Referring to FIG. 2, FIG. 2 is a flowchart of a manufacturing method of the display panel according to embodiment 1 of the present disclosure. The method comprises the following steps:

step S1: providing the thin film transistor substrate 10, and manufacturing the anode layer 11 on the thin film transistor substrate 10.

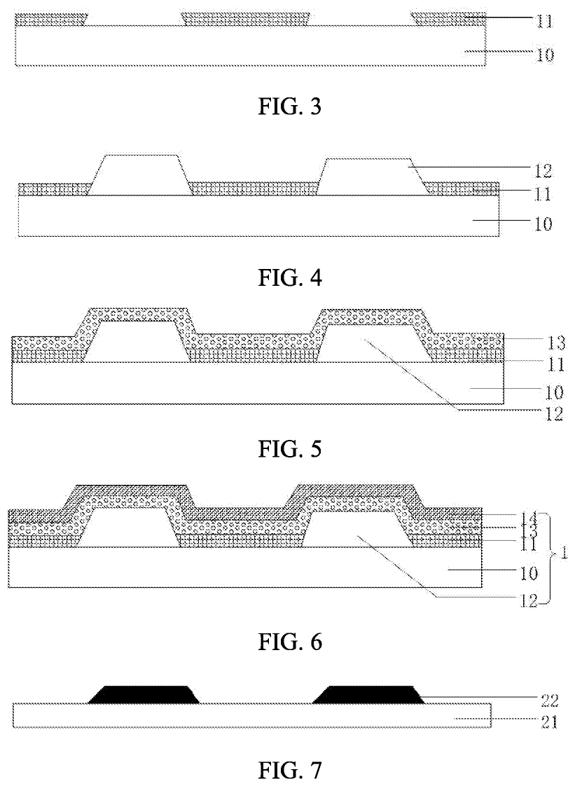

Referring to FIG. 3, FIG. 3 is a schematic structural diagram of the display panel when manufactured in step S1 according to embodiment 1 of the present disclosure.

Step S2: manufacturing the flat layer 12 on the anode layer 11.

Referring to FIG. 4, FIG. 4 is a schematic structural diagram of the display panel when manufactured in step S2 according to embodiment 1 of the present disclosure.

Wherein, the flat layer 12 is manufactured by chemical vapor deposition.

Step S3: manufacturing the organic light-emitting layer 13 on the flat layer 12.

Referring to FIG. 5, FIG. 5 is a schematic structural diagram of the display panel when manufactured in step S3 according to embodiment 1 of the present disclosure.

Step S4: manufacturing the cathode layer 14 on the organic light-emitting layer 13, and forming the thin film transistor backboard 1.

Referring to FIG. 6, FIG. 6 is a schematic structural diagram of the display panel when manufactured in step S4 according to embodiment 1 of the present disclosure.

Step S5: providing the glass substrate 21, and manufacturing the black matrix 22 on the glass substrate 21.

Referring to FIG. 7, FIG. 7 is a schematic structural diagram of the display panel when manufactured in step S5 according to embodiment 1 of the present disclosure.

Step S6: manufacturing the RGB color resist layer 23 on the black matrix 22.

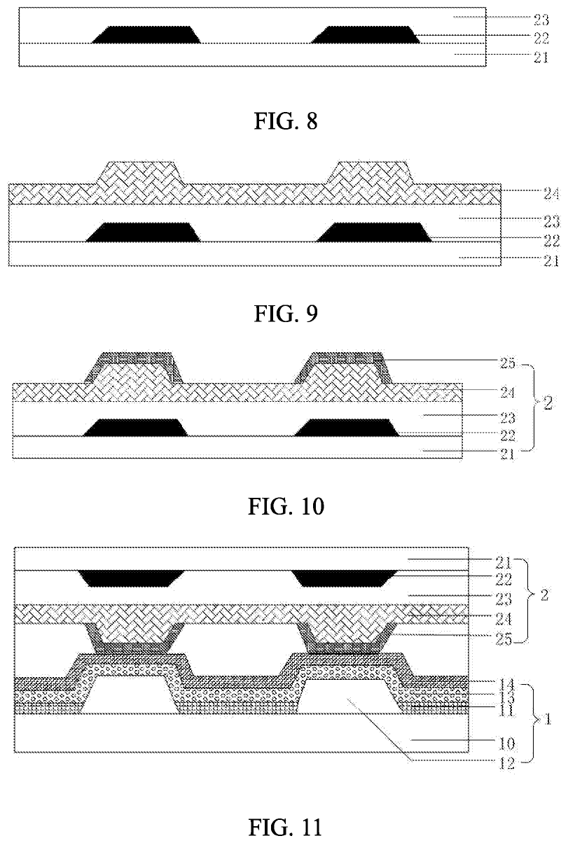

Referring to FIG. 8, FIG. 8 is a schematic structural diagram of the display panel when manufactured in step S6 according to embodiment 1 of the present disclosure.

Step S7: manufacturing the photoresist layer 24 on the RGB color resist layer 23, wherein the thickness of the photoresist layer 24 which is on the black matrix 22 area is greater than the thickness of the photoresist layer 24 which is not on the black matrix 22 area.

Referring to FIG. 9, FIG. 9 is a schematic structural diagram of the display panel when manufactured in step S7 according to embodiment 1 of the present disclosure.

Wherein, the photoresist layer 24 is manufactured by a semi-transparent mask technique or a method of two masks.

Step S8: manufacturing the auxiliary cathode layer 25 on the photoresist layer 24 which is on the black matrix 22 area, and forming the color filter substrate 2.

Referring to FIG. 10, FIG. 10 is a schematic structural diagram of the display panel when manufactured in step S8 according to embodiment 1 of the present disclosure.

Step S9: bonding the thin film transistor backboard 1 to the color filter substrate 2 by a packaging method.

Referring to FIG. 11, FIG. 11 is a schematic structural diagram of the display panel when manufactured in step S9 according to embodiment 1 of the present disclosure.

Use the semi-transparent mask technique or the method of two masks to manufacture the photoresist layer which is thicker directly on the black matrix, and then manufacture the auxiliary cathode layer on the photoresist layer which is on the black matrix area. The auxiliary cathode layer is higher because the below photoresist layer is higher, facilitating the auxiliary cathode layer to connect to the cathode layer when the color filter substrate is bonded to the thin film transistor backboard. Because the impedance of the auxiliary cathode layer is less, after contacting with the cathode layer, the resistance of the cathode layer will decrease at the same time, thereby reducing the voltage drop, improving the problem of voltage drops in display panels, and improving quality of display panels.

The present disclosure has been described with a preferred embodiment thereof. The preferred embodiment is not intended to limit the present disclosure, and it is understood that many changes and modifications to the described embodiment can be carried out without departing from the scope and the spirit of the disclosure. The changes and modifications should also be regarded as the scope of the disclosure.

What is claimed is:

1. A color filter substrate, comprising an auxiliary cathode layer, a photoresist layer, an RGB color resist layer, a black matrix, and a glass substrate disposed in sequence; wherein a thickness of the photoresist layer which is directly below the black matrix area is greater than a thickness of the photoresist layer which is not directly below the black matrix area; and the auxiliary cathode layer is disposed under the photoresist layer which is under the black matrix area.

2. A display panel, comprising a thin film transistor substrate, an anode layer, a flat layer, an organic light emitting layer, a cathode layer, and the color filter substrate according to claim 1 disposed in sequence; wherein the auxiliary cathode layer is connected to the cathode layer.

3. The display panel according to claim 2, wherein a material for the anode layer comprises one of indium tin metal oxide or silver metal.

4. The display panel according to claim 2, wherein a material of the flat layer is a polyimide film.

5. The display panel according to claim 2, wherein the thin film transistor substrate comprises a substrate layer, a light-shielding layer, a buffer layer, an active layer, a gate insulating layer, a gate layer, an interlayer dielectric layer, a source/drain layer, and an organic layer, which are disposed in sequence.

6. The display panel according to claim 2, wherein a material of the source/drain layer comprises one of molybdenum, aluminum, titanium, copper, or indium tin metal oxide.

7. A manufacturing method of the display panel according to claim 2, comprising the following steps:
step S1: providing the thin film transistor substrate and manufacturing the anode layer on the thin film transistor substrate;
step S2: manufacturing the flat layer on the anode layer;
step S3: manufacturing the organic light-emitting layer on the flat layer;
step S4: manufacturing the cathode layer on the organic light-emitting layer, and forming a thin film transistor backboard;
step S5: providing the glass substrate, and manufacturing the black matrix on the glass substrate;
step S6: manufacturing the RGB color resist layer on the black matrix;
step S7: manufacturing the photoresist layer on the RGB color resist layer, wherein the thickness of the photoresist layer which is on the black matrix area is greater than the thickness of the photoresist layer which is not on the black matrix area;
step S8: manufacturing the auxiliary cathode layer on the photoresist layer which is on the black matrix area, and forming the color filter substrate; and
step S9: bonding the thin film transistor backboard to the color filter substrate.

8. The manufacturing method according to claim 7, wherein the flat layer is manufactured by chemical vapor deposition.

9. The manufacturing method according to claim 7, wherein the photoresist layer is manufactured by a semi-transparent mask technique or a method of two masks.

10. The manufacturing method according to claim 7, wherein the step S9 of bonding the thin film transistor backboard to the color filter substrate is by a packaging method.

11. The manufacturing method according to claim 7, wherein a material for the anode layer comprises one of indium tin metal oxide or silver metal.

12. The manufacturing method according to claim 7, wherein a material of the flat layer is a polyimide film.

13. The manufacturing method according to claim 7, wherein the thin film transistor substrate comprises a substrate layer, a light-shielding layer, a buffer layer, an active layer, a gate insulating layer, a gate layer, an interlayer dielectric layer, a source/drain layer, and an organic layer, which are disposed in sequence.

14. The manufacturing method according to claim 7, wherein a material of the source/drain layer comprises one of molybdenum, aluminum, titanium, copper, or indium tin metal oxide.
